(19) United States
(12) Patent Application Publication
(10) Pub. No.: US 2026/0233331 A1
(43) Pub. Date: Aug. 13, 2026

(54) LASER PROCESSING APPARATUS, METHOD OF MANUFACTURING DISPLAY DEVICE USING THE APPARATUS, AND ELECTRONIC DEVICE INCLUDING DISPLAY DEVICE MANUFACTURED USING THE METHOD

(71) Applicant: Samsung Display Co., LTD., Yongin-si (KR)

(72) Inventors: AKIFUMI SANGU, Yongin-si (KR); YOUNGSU CHAE, Yongin-si (KR); JUNGHYUN KIM, Yongin-si (KR); CHEOLHO PARK, Yongin-si (KR)

(21) Appl. No.: 19/353,926

(22) Filed: Oct. 9, 2025

(30) Foreign Application Priority Data
Feb. 7, 2025 (KR) 10-2025-0015983

(51) Int. Cl. B23K 26/06; B23K 26/073; B23K 101/36

(52) U.S. Cl. CPC B23K 26/0648; B23K 26/073; B23K 2101/36

(57) ABSTRACT

A laser processing apparatus includes: a laser irradiation part which radiates solid laser beams; a homogenizer which homogenizes the solid laser beams; a first lens group which receives a first light passed through the homogenizer, has a negative focal length of greater than about −1000 millimeters and less than about −300 millimeters, and outputs a second light different from the first light; and a second lens group which receives the second light passed through the first lens group, has a positive focal length of greater than about 100 millimeters and less than about 300 millimeters, and outputs an output light to an irradiation object. An energy intensity of the output light has a super-Gaussian profile of greater than or equal to about 2.5 orders and less than or equal to about 7.5 orders.

This application claims priority to Korean Patent Application No. 10-2025-0015983, filed on Feb. 7, 2025, and all the benefits accruing therefrom under 35 U.S.C. § 119, the content of which in its entirety is herein incorporated by reference.

### BACKGROUND

### 1. Field

The present disclosure relates generally to a laser processing apparatus. More particularly, the present disclosure relates to a laser processing apparatus that radiates an output light having a super-Gaussian profile and a method of manufacturing a display device using the apparatus.

### 2. Description of the Related Art

With the development of information technology, the importance of a display device, which is a connection medium between a user and information, has been highlighted. For example, the use of display devices such as liquid crystal display (LCD) device, organic light emitting diode (OLED) display device, plasma display panel (PDP) device, quantum dot display device or the like are widely used in various fields.

The display device may include a display substrate having flexibility. In a case where the display device includes the display substrate having flexibility, the display substrate must be supported during a manufacturing process of the display device. Therefore, after forming the display substrate on a carrier substrate, the carrier substrate may be removed after the manufacturing process of the display device. The carrier substrate may be removed by various methods, and among the methods, research is being conducted on a laser lift-off method using a laser.

### SUMMARY

Embodiments provide a laser processing apparatus with improved reliability of a peeling process.

Embodiments provide a method of manufacturing a display device using the laser processing apparatus.

Embodiments provide an electronic device including a display device manufactured by the method of manufacturing the display device.

A laser processing apparatus according to an embodiment of the present disclosure includes: a laser irradiation part which radiates solid laser beams; a homogenizer which homogenizes the solid laser beams; a first lens group which receives a first light passed through the homogenizer, has a negative focal length of greater than about −1000 millimeters and less than about −300 millimeters, and outputs a second light different from the first light; and a second lens group which receives the second light passed through the first lens group, has a positive focal length of greater than about 100 millimeters and less than about 300 millimeters, and outputs an output light to an irradiation object. In such an embodiment, an energy intensity of the output light has a super-Gaussian profile of greater than or equal to about 2.5 orders and less than or equal to about 7.5 orders.

In an embodiment, a distance between the first lens group and the second lens group may be greater than about 2000 millimeters and less than about 6000 millimeters.

In an embodiment, the irradiation object may include a first side extending in a first direction and a second side contacting the first side and extending in a second direction intersecting the first direction. In such an embodiment, a length of the second side may be greater than a length of the first side. In such an embodiment, the energy intensity of the output light measured in the first direction may have the super-Gaussian profile of greater than or equal to about 2.5 orders and less than or equal to about 7.5 orders.

In an embodiment, the energy intensity of the output light measured in the first direction may have a super-Gaussian profile of greater than or equal to about 4.0 orders and less than or equal to about 7.5 orders.

In an embodiment, the first lens group may include a first lens, a second lens, and a third lens, and the second lens group may include a fourth lens. In such an embodiment, the first to fourth lenses may be sequentially arranged along a direction parallel to an optical axis of light traveling toward the irradiation object. In such an embodiment, a composite focal length of the first lens, the second lens, and the third lens may be greater than about −1000 millimeters and less than about −300 millimeters. In such an embodiment, a focal length of the fourth lens may be greater than about 100 millimeters and less than about 300 millimeters.

In an embodiment, each of the first lens and the third lens may have a negative refractive power, and each of the second lens and the fourth lens may have a positive refractive power.

In an embodiment, each of a first light-incident surface of the first lens and a third light-incident surface of the third lens may have a negative radius of curvature, and each of a second light-incident surface of the second lens and a fourth light-incident surface of the fourth lens may have a positive radius of curvature.

In an embodiment, each of the first lens, the second lens, and the third lens may have a negative refractive power, and the fourth lens may have a positive refractive power.

In an embodiment, each of a first light-incident surface of the first lens, a second light-incident surface of the second lens, and a third light-incident surface of the third lens may have a negative radius of curvature, and a fourth light-incident surface of the fourth lens may have a positive radius of curvature.

In an embodiment, the apparatus may further include a shaping lens arranged between the laser irradiation part and the homogenizer. In such an embodiment, the shaping lens may transform an initial shape of the solid laser beams into a laser having a first shape.

In an embodiment, the homogenizer may rotate the laser having the first shape and may transform the laser having the first shape into a laser having a rotated shape of the first shape.

A method of manufacturing a display device according to an embodiment of the present disclosure includes: providing a laser processing apparatus including a laser irradiation part which radiates solid laser beams, a homogenizer which homogenizes the solid laser beams, a first lens group which receives a light passed through the homogenizer and has a negative focal length of greater than about −1000 millimeters and less than about −300 millimeters, and a second lens group which receives a light passed through the first lens group and has a positive focal length of greater than about 100 millimeters and less than about 300 millimeters; forming a display substrate on a first surface of a carrier substrate; forming a light-emitting element on the display substrate; and peeling off the carrier substrate from the display substrate by radiating output light of the laser processing apparatus to a second surface, which is opposite to the first surface, of the carrier substrate using the laser processing apparatus. In such an embodiment, an energy intensity of the output light has a super-Gaussian profile of greater than or equal to about 2.5 orders and less than or equal to about 7.5 orders.

In an embodiment, a distance between the first lens group and the second lens group may be greater than about 2000 millimeters and less than about 6000 millimeters.

In an embodiment, the display substrate may include a first side extending in a first direction and a second side contacting the first side and extending in a second direction intersecting the first direction. In such an embodiment, a length of the second side may be greater than a length of the first side. In such an embodiment, the energy intensity of the output light measured in the first direction may have the super-Gaussian profile of greater than or equal to about 2.5 orders and less than or equal to about 7.5 orders.

In an embodiment, the energy intensity of the output light measured in the first direction may have a super-Gaussian profile of greater than or equal to about 4.0 orders and less than or equal to about 7.5 orders.

In an embodiment, the laser processing apparatus may move in the second direction.

In an embodiment, the first lens group may include first to third lenses sequentially arranged along a direction parallel to an optical axis of light traveling toward the carrier substrate. In such an embodiment, a composite focal length of the first to third lenses may be greater than about −1000 millimeters and less than about −300 millimeters.

In an embodiment, each of the first lens and the third lens may have a negative refractive power, and the second lens may have a positive refractive power.

In an embodiment, each of the first lens, the second lens, and the third lens may have a negative refractive power.

An electronic device according to an embodiment of the present disclosure includes: a display device manufactured by using the method described above; and a processor which transmits an image data signal and an input control signal to the display device.

A laser processing apparatus according to embodiments of the present disclosure may include a laser irradiation part that radiates solid laser beams, a homogenizer that homogenizes the solid laser beams, a first lens group that receives a light passed through the homogenizer and has a negative focal length of greater than about −1000 millimeters and less than about −300 millimeters, and a second lens group that receives a light passed through the first lens group and has a positive focal length of greater than about 100 millimeters and less than about 300 millimeters. In embodiments, a distance between the first lens group and the second lens group may be greater than about 2000 millimeters and less than about 6000 millimeters. In such embodiments, the energy intensity of output light output by the laser processing apparatus may have a super-Gaussian profile of greater than or equal to about 2.5 orders and less than or equal to about 7.5 orders.

In such embodiments, since the energy intensity of the output light has a super-Gaussian profile of greater than or equal to about 2.5 orders and less than or equal to about 7.5 orders, the output light may process an irradiation object (e.g., a carrier substrate and a display substrate) with a relatively uniform energy intensity without excessively exceeding a processing threshold. Accordingly, in a process of processing the irradiation object using the output light, damage to the irradiation object may be minimized. That is, the reliability of the process of processing the irradiation object may be improved.

### BRIEF DESCRIPTION OF THE DRAWINGS

Illustrative, non-limiting embodiments will be more clearly understood from the following detailed description in conjunction with the accompanying drawings.

FIG. 1 is a view illustrating a laser processing system according to an embodiment of the present disclosure.

FIG. 2 is a plan view illustrating a movement direction of a laser processing apparatus included in the laser processing system of FIG. 1.

FIG. 3 is a view illustrating a laser processing apparatus included in the laser processing system of FIG. 1.

FIG. 4 is an enlarged view of the area A of FIG. 3.

FIG. 5 is an enlarged view of the area B of FIG. 4.

FIG. 6 is a diagram illustrating an intensity profile of an output light emitted from the laser processing apparatus of FIG. 3.

FIG. 7 is a view illustrating an embodiment of a first lens group and a second lens group included in the laser processing apparatus of FIG. 3.

FIG. 8 is a view illustrating an embodiment of a first lens group and a second lens group included in the laser processing apparatus of FIG. 3.

FIG. 9 is a view illustrating an example of a first lens group and a second lens group included in a laser processing apparatus according to a comparative example.

FIGS. 10A, 10B, 10C, 10D, and 10E are diagrams illustrating an intensity profile of an output light emitted from a laser processing apparatus according to embodiments of the present disclosure.

FIG. 11 is a diagram illustrating an intensity profile of an output light emitted from a laser processing apparatus according to a comparative example.

FIGS. 12, 13, 14, 15, 16, and 17 are views illustrating a method of manufacturing a display device according to an embodiment of the present disclosure.

FIG. 18 is a block diagram of an electronic device according to an embodiment of the present disclosure.

FIG. 19 is a schematic view of an electronic device according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described in detail with reference to the accompanying drawings. The same reference numerals are used for the same components in the drawings, and any repetitive detailed descriptions of the same components will be omitted or simplified.

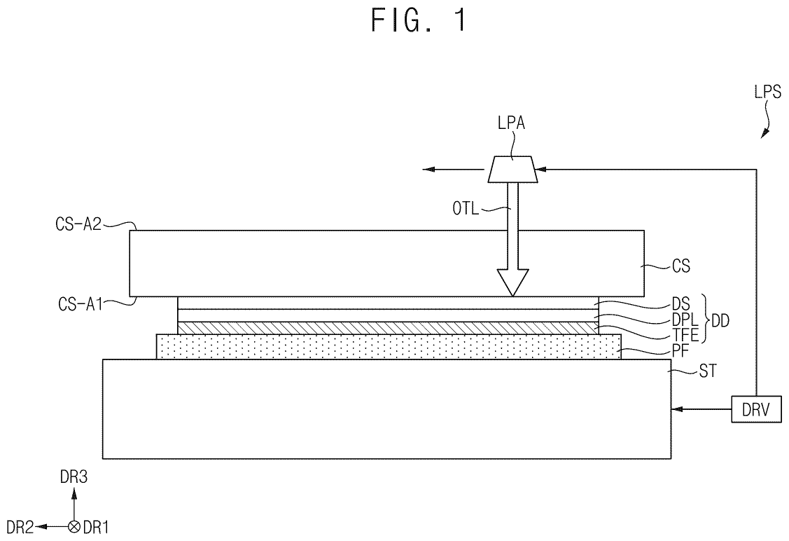

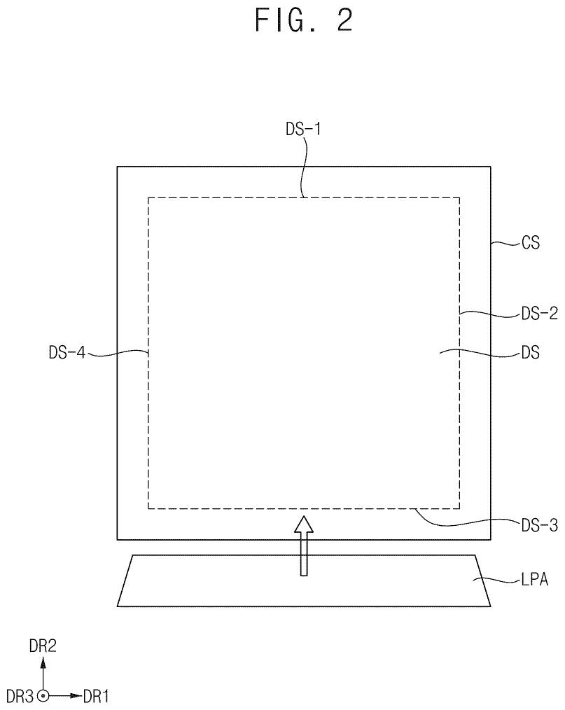

FIG. 1 is a view illustrating a laser processing system according to an embodiment of the present disclosure. FIG. 2 is a plan view illustrating a movement direction of a laser processing apparatus included in the laser processing system of FIG. 1.

In this specification, a plane may be defined by a first direction DR1 and a second direction DR2 intersecting the first direction DR1. For example, the first direction DR1 and the second direction DR2 may be perpendicular to each other. A direction normal to the plane may be a third direction DR3. In other words, the third direction DR3 may be perpendicular to each of the first direction DR1 and the second direction DR2. As used herein the “plan view” is a view in the third direction DR3.

Referring to FIGS. 1 and 2, a laser processing system LPS according to an embodiment of the present disclosure may include a stage ST, a laser processing apparatus LPA, and a driver DRV.

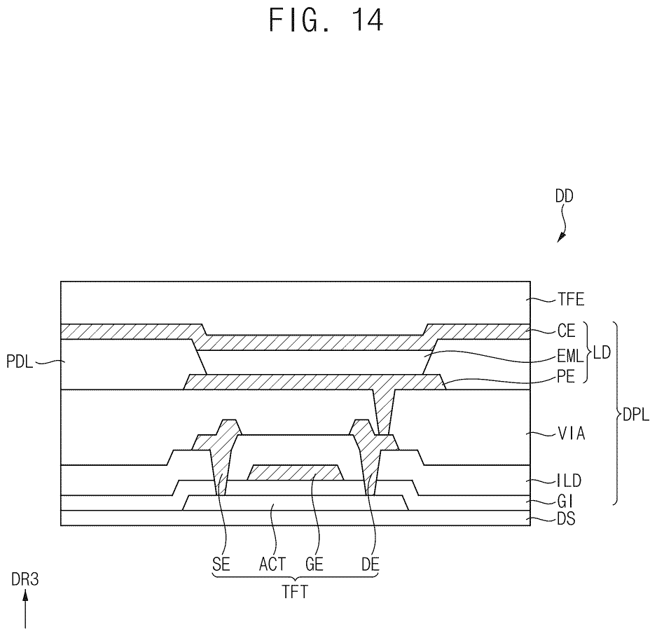

The stage ST may include a flat upper surface. A carrier substrate CS and a display substrate DS may be loaded on the stage ST. In an embodiment, for example, a display device DD formed on a first surface CS-A1 of the carrier substrate CS may be positioned on the upper surface of the stage ST. In addition, a protective film PF formed on the display device DD may be positioned on the upper surface of the stage ST. In other words, the carrier substrate CS may face the laser processing apparatus LPA, and the protective film PF may face the stage ST. In an embodiment, the display device DD may include the display substrate DS, a display element layer DPL, and an encapsulation layer TFE. A detailed description thereof will be provided below with reference to FIG. 14.

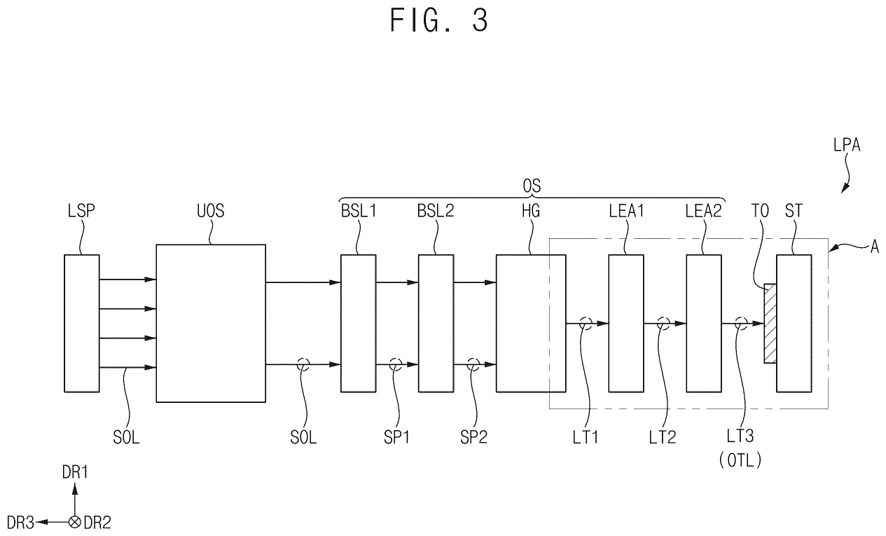

The laser processing apparatus LPA may be positioned above the stage ST. In an embodiment, for example, the laser processing apparatus LPA may be positioned above the carrier substrate CS. The laser processing apparatus LPA may radiate an output light OTL to a second surface CS-A2 of the carrier substrate CS, which is opposite to the first surface CS-A1 thereof. The laser processing apparatus LPA may separate the carrier substrate CS and the display substrate DS by radiating the output light OTL. In an embodiment, for example, the laser processing apparatus LPA may radiate the output light OTL having energy capable of breaking a bond between the carrier substrate CS and the display substrate DS. The laser processing apparatus LPA may include a laser irradiation part (LSP, refer to FIG. 3) and an optical system (OS, refer to FIG. 3). A detailed description thereof will be provided below with reference to FIG. 3.

The laser processing apparatus LPA may be transported by the driver DRV. Accordingly, the output light OTL may scan a boundary surface between the display substrate DS and the carrier substrate CS.

In an embodiment, for example, the display substrate DS may have a rectangular planar shape. In an embodiment, as illustrated in FIG. 2, the display substrate DS may include a first side DS-1, a second side DS-2, a third side DS-3, and a fourth side DS-4. The first side DS-1 may extend in the first direction DR1. The third side DS-3 may extend parallel to and facing the first side DS-1. The second side DS-2 may contact the first side DS-1 and the third side DS-3 and may extend in the second direction DR2. The fourth side DS-4 may contact the first side DS-1 and the third side DS-3 and may extend parallel to and facing the second side DS-2. The first to fourth sides DS-1, DS-2, DS-3, and DS-4 may define an edge of the display substrate DS.

In an embodiment, the display substrate DS may have a rectangular planar shape having a short side extending in the first direction DR1 and a long side extending in the second direction DR2. In an embodiment, for example, a length of the second side DS-2 may be greater than a length of the first side DS-1, and a length of the fourth side DS-4 may be greater than a length of the third side DS-3.

In an embodiment, the laser processing apparatus LPA may move in a longitudinal direction of the display substrate DS. In an embodiment, for example, the laser processing apparatus LPA may move in the second direction DR2 and in an opposite direction of the second direction DR2.

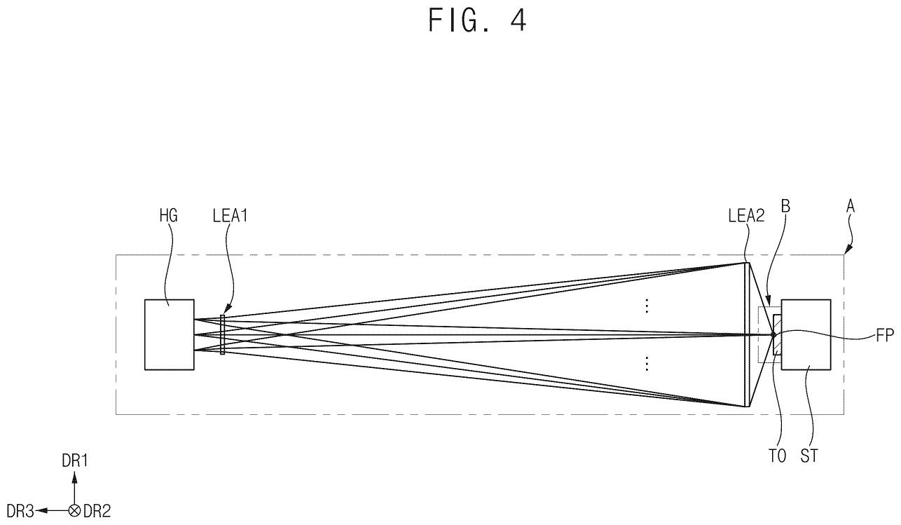

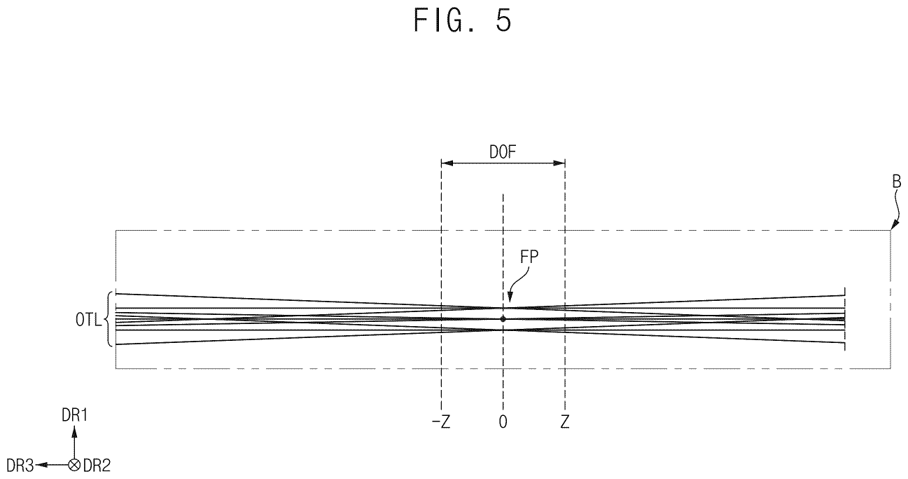

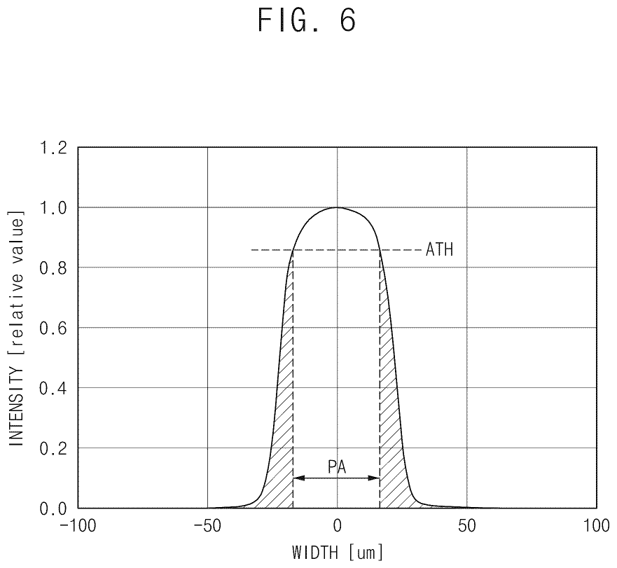

FIG. 3 is a view illustrating a laser processing apparatus included in the laser processing system of FIG. 1. FIG. 4 is an enlarged view of the area A of FIG. 3. FIG. 5 is an enlarged view of the area B of FIG. 4. For ease of illustration and description, an irradiation object TO is not illustrated in FIG. 5. FIG. 6 is a diagram illustrating an intensity profile of an output light emitted from the laser processing apparatus of FIG. 3.

Referring to FIG. 3, an embodiment of the laser processing apparatus LPA may include a laser irradiation part LSP, a sub-optical system UOS, and an optical system OS.

The laser irradiation part LSP may radiate solid laser beams SOL. In an embodiment, for example, the solid laser beams SOL may be ultraviolet light having a wavelength of about 343 nanometers and may have a pulse width of nanoseconds. However, the present disclosure is not necessarily limited thereto. In an embodiment, as shown in FIG. 3, the laser irradiation part LSP may radiate four solid laser beams SOL, but the present disclosure is not necessarily limited thereto. The number of the solid laser beams SOL radiated by the laser irradiation part LSP may be changed or modified according to embodiments.

In an embodiment, the sub-optical system UOS may be arranged between the laser irradiation part LSP and the optical system OS. The sub-optical system UOS may combine the solid laser beams SOL provided by the laser irradiation part LSP. Accordingly, the sub-optical system UOS may provide a smaller number of the solid laser beams SOL to the optical system OS than the number of the solid laser beams SOL provided by the laser irradiation part LSP. In an embodiment, for example, the laser irradiation part LSP may radiate four solid laser beams SOL, and the sub-optical system UOS may provide two solid laser beams SOL to the optical system OS, but the present disclosure is not necessarily limited thereto. In another embodiment, the sub-optical system UOS may be omitted.

The optical system OS may convert the solid laser beams SOL into the output light OTL. The output light OTL converted by the optical system OS may be radiated to an irradiation object TO. The irradiation object TO may be loaded on the stage ST. In this case, the irradiation object TO may correspond to the carrier substrate CS and the display substrate DS of FIG. 1.

The optical system OS may include a first shaping lens BSL1, a second shaping lens BSL2, a homogenizer HG, a first lens group LEA1, and a second lens group LEA2. The solid laser beams SOL radiated from the laser irradiation part LSP may be converted into the output light OTL by passing sequentially through the first shaping lens BSL1, the second shaping lens BSL2, the homogenizer HG, the first lens group LEA1, and the second lens group LEA2.

The first shaping lens BSL1 may be arranged between the laser irradiation part LSP and the second shaping lens BSL2. The second shaping lens BSL2 may be arranged between the first shaping lens BSL1 and the homogenizer HG. The first shaping lens BSL1 may transform an initial shape of the solid laser beams SOL into a laser SP1 having a first shape, and the second shaping lens BSL2 may transform the laser SP1 having the first shape into a laser SP2 having a second shape. In an embodiment, for example, each of the solid laser beams SOL may have a circular planar shape, and each of the first shape and the second shape may be an elliptical planar shape. A diameter of the circular shape of the solid laser beam SOL may be greater than a length of a short axis of the first shape, and the length of the short axis of the first shape may be greater than a length of a short axis of the second shape.

The homogenizer HG may be arranged between the second shaping lens BSL2 and the first lens group LEA1. The homogenizer HG may homogenize the solid laser beams SOL passed through the second shaping lens BSL2. In addition, the homogenizer HG may rotate the laser SP2 having the second shape. That is, the homogenizer HG may rotate the laser SP2 having the second shape to transform the laser SP2 having the second shape into a laser having a rotated shape of the second shape. In an embodiment, for example, the homogenizer HG may rotate the second shape by about 90 degrees.

The homogenizer HG may output a first light LT1 by mixing the solid laser beams SOL passed through the second shaping lens BSL2. In an embodiment, the first light LT1 may have a linear shape. In an embodiment, the first light LT1 may have a beam shape including a long axis direction and a short axis direction.

Referring further to FIG. 4, the first lens group LEA1 may be arranged between the homogenizer HG and the irradiation object TO. In an embodiment, for example, the first lens group LEA1 may be arranged between the homogenizer HG and the second lens group LEA2. The first light LT1 passed through the homogenizer HG may be incident on the first lens group LEA1. The first lens group LEA1 may output a second light LT2 by transforming the first light LT1. In an embodiment, the first lens group LEA1 may have a negative focal length. Here, a negative focal length may mean that a focal point of the lens is defined on a left side of the lens based on FIG. 3, i.e., on a same side as the homogenizer HG. The first lens group LEA1 may refract and diffuse the first light LT1.

The first lens group LEA1 may include only one lens or may include at least two lenses. In an embodiment, a first focal length of the first lens group LEA1 may be greater than about −1000 millimeters and less than about −300 millimeters. In an embodiment where the first lens group LEA1 includes only one lens having a negative refractive power, a focal length of the lens may be greater than about −1000 millimeters and less than about −300 millimeters. In an embodiment where the first lens group LEA1 includes a plurality of lenses, a composite focal length of the plurality of lenses may be greater than about −1000 millimeters and less than about −300 millimeters.

The second lens group LEA2 may be arranged between the first lens group LEA1 and the irradiation object TO. The second lens group LEA2 may be spaced apart from the first lens group LEA1. In an embodiment, a distance between the first lens group LEA1 and the second lens group LEA2 may be greater than about 2000 millimeters and less than about 6000 millimeters.

The second light LT2 passed through the first lens group LEA1 may be incident on the second lens group LEA2. The second lens group LEA2 may output a third light LT3 by transforming the second light LT2. Here, the third light LT3 may be the output light OTL. In an embodiment, the second lens group LEA2 may have a positive focal length. Here, a positive focal length may mean that a focal point of the lens is defined on a right side of the lens based on FIG. 3, i.e., on a same as the irradiation object TO. The second lens group LEA2 may refract and focus the second light LT2. The second lens group LEA2 may focus the second light LT2 and output the third light (LT3, or the output light OTL) to the irradiation object TO.

In an embodiment, the second lens group LEA2 may include only one lens or may include at least two lenses. In an embodiment, a second focal length of the second lens group LEA2 may be greater than about 100 millimeters and less than about 300 millimeters. In an embodiment where the second lens group LEA2 includes only one lens having a positive refractive power, a focal length of the lens may be greater than about 100 millimeters and less than about 300 millimeters. In an embodiment where the second lens group LEA2 includes a plurality of lenses, a composite focal length of the plurality of lenses may be greater than about 100 millimeters and less than about 300 millimeters.

Referring further to FIGS. 5 and 6, the output light OTL converted by the optical system OS may be a Gaussian beam having a super-Gaussian profile. In an embodiment, for example, when viewed in a propagation direction of the output light OTL, the intensity of the energy measured in a short axis direction (e.g., the first direction DR1) may have a super-Gaussian profile.

The second lens group LEA2 may focus the output light OTL to a focal point FP. In this case, the output light OTL may not converge to a single point, but may form a light-collecting surface near the focal point FP. As illustrated in FIG. 4, the focal point FP may overlap the irradiation object TO.

As illustrated in FIG. 5, the output light OTL may form a beam waist with the smallest amplitude at the focal point FP. Based on FIG. 5, if a point positioned to the right of the focal point FP and having a width equal to \sqrt{2} times the width of the base waist is defined as a point Z, and a point positioned to the left of the focal point FP and having a width equal to \sqrt{2} times the width of the base waist is defined as a point −Z, the depth of focus (DOF) may be defined as a distance between the Z point and the −Z point.

In the graph of FIG. 6, the X-axis coordinate represents a width of the output light OTL corresponding to a length of the short axis direction (e.g., a length of the first direction DR1) at the irradiation object TO, and the Y-axis coordinate represents the intensity of the energy of the output light OTL.

Among the output light OTL, a laser beam having an intensity greater than or equal to a processing threshold ATH may process the irradiation object TO. Here, the processing threshold ATH may mean a minimum value of energy to break the bond between the carrier substrate (CS, refer to FIG. 1) and the display substrate (DS, refer to FIG. 1). Accordingly, the irradiation object TO may be processed in a processing area PA where a laser beam having an intensity greater than or equal to the processing threshold ATH among the output light OTL is distributed.

Among the output light OTL, a laser beam having an intensity lower than the processing threshold ATH may provide thermal energy to the irradiation object TO. Accordingly, heat may be transferred to the irradiation object TO at an edge portion (a hatched area of FIG. 6) where a laser beam having an intensity lower the processing threshold ATH among the output light OTL is distributed.

As illustrated in FIG. 6, the energy intensity measured in the short axis direction of the output light OTL may have a super-Gaussian profile. In an embodiment, the energy intensity measured in the short axis direction of the output light OTL may have a super-Gaussian profile of greater than or equal to about 2.5 orders and less than or equal to about 7.5 orders. In an embodiment, for example, the energy intensity measured in the short axis direction of the output light OTL may have a super-Gaussian profile of greater than or equal to about 4.0 orders and less than or equal to about 7.5 orders. As the order of the super-Gaussian profile increases, an upper surface of a central portion may have a gentle (or flat) profile, and the energy intensity may decrease rapidly at an edge portion. Since the energy intensity of the output light OTL has a super-Gaussian profile of greater than or equal to about 2.5 orders and less than or equal to about 7.5 orders in the short axis direction, the output light OTL may process the irradiation object TO without excessively exceeding the processing threshold ATH with a relatively uniform energy intensity. Accordingly, damage to the irradiation object TO may be minimized in a process of processing the irradiation object TO using the output light OTL. In addition, an area of the laser beam having an intensity lower than the processing threshold ATH may be relatively reduced, and thermal deformation of the irradiation object TO due to thermal energy may be minimized. That is, the reliability of the process of processing the irradiation object TO may be improved.

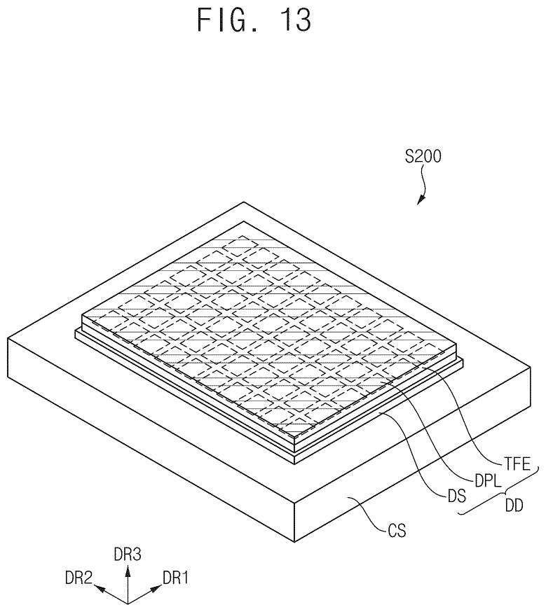

In a case where the energy intensity measured in the short axis direction of the output light OTL has a super-Gaussian profile of less than about 2.5 orders (refer to FIG. 11), an upper surface of a central portion may have a sharp (or steep) profile. In this case, the irradiation object TO may receive superfluous energy that excessively exceeds the processing threshold ATH, which may cause damage to the irradiation object TO.

In an embodiment, as shown in FIG. 6, the energy intensity measured in the short axis direction of the output light OTL may have a super-Gaussian profile of about 5.3 orders, but the present disclosure is not necessarily limited thereto.

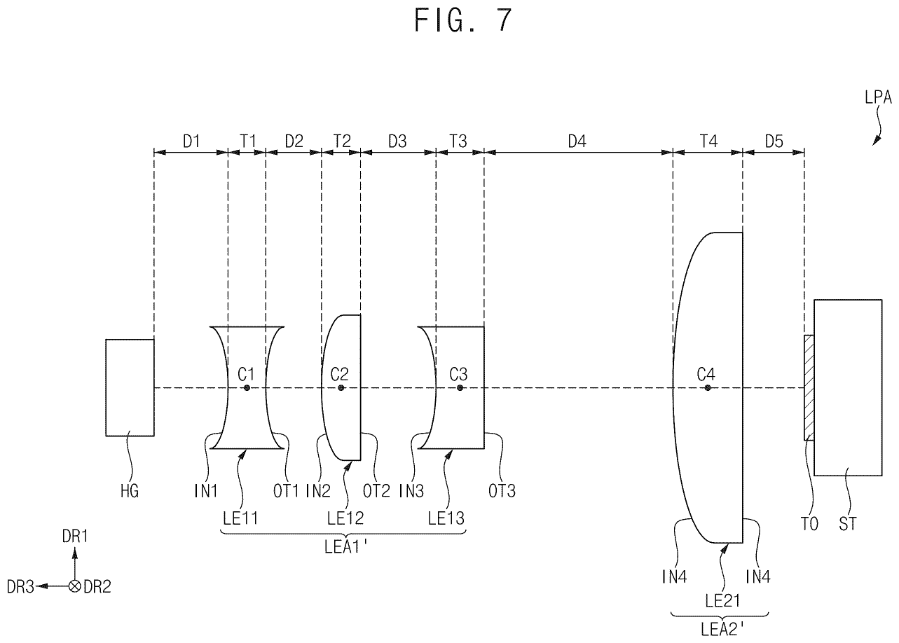

FIG. 7 is a view illustrating an embodiment of a first lens group and a second lens group included in the laser processing apparatus of FIG. 3.

Referring to FIG. 7, in an embodiment, the laser processing apparatus LPA may include the homogenizer HG, a first lens group LEA1′, and a second lens group LEA2′. In FIG. 7, for convenience of illustration, the laser irradiation part LSP, the sub-optical system UOS, the first shaping lens BSL1, and the second shaping lens BSL2 described above with reference to FIG. 3 are omitted.

The first lens group LEA1′ may be arranged between the homogenizer HG and the second lens group LEA2′. In an embodiment, the first lens group LEA1′ may include at least two lenses. In an embodiment, for example, the first lens group LEA1′ may include a first lens LE11, a second lens LE12, and a third lens LE13.

The second lens group LEA2′ may be arranged between the first lens group LEA1′ and the irradiation object TO. The second lens group LEA2′ may be spaced apart from the first lens group LEA1′. In an embodiment, the second lens group LEA2′ may include only one lens. In an embodiment, for example, the second lens group LEA2′ may include a fourth lens LE21. However, the present disclosure is not necessarily limited thereto, and the second lens group LEA2′ may include a plurality of lenses in another embodiment.

The first to fourth lenses LE11, LE12, LE13, and LE21 may be sequentially arranged along a direction parallel to an optical axis of light passing through the homogenizer HG and proceeding toward the irradiation object TO. An imaginary line connecting centers C1, C2, C3, and C4 of the first to fourth lenses LE11, LE12, LE13, and LE21 may be parallel to the third direction DR3.

Among the first to fourth lenses LE11, LE12, LE13, and LE21, a distance between the first lens LE11, which is closest to the homogenizer HG, and the homogenizer HG may be defined as a first distance D1. The first to fourth lenses LE11, LE12, LE13, and LE21 may be spaced apart from each other. A distance between the first lens LE11 and the second lens LE12 may be defined as a second distance D2. A distance between the second lens LE12 and the third lens LE13 may be defined as a third distance D3. A distance between the third lens LE13 and the fourth lens LE21 may be defined as a fourth distance D4. A distance between the fourth lens LE21 and the irradiation object TO may be defined as a fifth distance D5.

Each of the first to fourth lenses LE11, LE12, LE13, and LE21 may include a light-incident surface and a light-emitting surface. Here, the light-incident surface may correspond to a surface where light is incident, and the light-emitting surface may correspond to a surface where light passing through a lens is emitted. With respect to one lens, the light-incident surface and the light-emitting surface may be opposite to each other. The light-incident surfaces of the first to fourth lenses LE11, LE12, LE13, and LE21 may be referred to as first to fourth light-incident surfaces IN1, IN2, IN3, and IN4, respectively. The light-emitting surfaces of the first to fourth lenses LE11, LE12, LE13, and LE21 may be referred to as first to fourth light-emitting surfaces OT1, OT2, OT3, and OT4, respectively.

Each of the first to fourth lenses LE11, LE12, LE13, and LE21 may have a thickness (e.g., a predetermined thickness). Here, the thickness of the lens may correspond to a distance from a center of the light-incident surface of the lens to a center of the light-emitting surface of the lens. The thicknesses of the first to fourth lenses LE11, LE12, LE13, and LE21 may be referred to as first to fourth thicknesses T1, T2, T3, and T4, respectively.

A first focal length of the first lens group LEA1′ may be greater than about −1000 millimeters and less than about −300 millimeters. In other words, a composite focal length of the first to third lenses LE11, LE12, and LE13 included in the first lens group LEA1′ may be greater than about −1000 millimeters and less than about −300 millimeters.

In an embodiment, each of the first lens LE11 and the third lens LE13 may have a negative refractive power, and the second lens LE12 may have a positive refractive power. However, the present disclosure is not necessarily limited thereto.

The first light-incident surface IN1 of the first lens LE11 may face the homogenizer HG, and the first light-emitting surface OT1 of the first lens LE11 may face the second light-incident surface IN2 of the second lens LE12. The first light-incident surface IN1 of the first lens LE11 may have a concave shape toward the first center C1. The radius of curvature of the first light-incident surface IN1 may be negative. When the radius of curvature is negative, the center of curvature is defined on a side where light is incident (e.g., the left side). The first light-emitting surface OT1 of the first lens LE11 may have a concave shape toward the first center C1. The radius of curvature of the first light-emitting surface OT1 may be positive. When the radius of curvature is positive, the center of curvature is defined on a side where light is emitted (e.g., the right side).

The second light-incident surface IN2 of the second lens LE12 may face the first light-emitting surface OT1, and the second light-emitting surface OT2 of the second lens LE12 may face the third light-incident surface IN3 of the third lens LE13. The second light-incident surface IN2 of the second lens LE12 may have a convex shape toward the second center C2. The radius of curvature of the second light-incident surface IN2 may be positive. The second light-emitting surface OT2 of the second lens LEl2 may be a surface perpendicular to the third direction DR3. That is, the second light-emitting surface OT2 may be a surface parallel to the first direction DR1. The radius of curvature of the second light-emitting surface OT2 may correspond to infinity.

The third light-incident surface IN3 of the third lens LE13 may face the second light-emitting surface OT2, and the third light-emitting surface OT3 of the third lens LE13 may face the fourth light-incident surface IN4 of the fourth lens LE21. The third light-incident surface IN3 of the third lens LE13 may have a concave shape toward the third center C3. The radius of curvature of the third light-incident surface IN3 may be negative. The third light-emitting surface OT3 of the third lens LE13 may be a surface perpendicular to the third direction DR3. That is, the third light-emitting surface OT3 may be a surface parallel to the first direction DR1. The radius of curvature of the third light-emitting surface OT3 may correspond to infinity.

A distance between the first lens group LEA1′ and the second lens group LEA2′ may be greater than about 2000 millimeters and less than about 6000 millimeters. In other words, the fourth distance D4 between the third lens LE13 and the fourth lens LE21 may be greater than about 2000 millimeters and less than about 6000 millimeters.

A second focal length of the second lens group LEA2′ may be greater than about 100 millimeters and less than about 300 millimeters. In other words, a focal length of the fourth lens LE21 included in the second lens group LEA2′ may be greater than about 100 millimeters and less than about 300 millimeters.

The fourth lens LE21 may have a positive refractive power. The fourth light-incident surface IN4 of the fourth lens LE21 may face the third light-emitting surface OT3, and the fourth light-emitting surface OT4 of the fourth lens LE21 may face the irradiation object TO. The fourth light-incident surface IN4 of the fourth lens LE21 may have a convex shape toward the fourth center C4. The radius of curvature of the fourth light-incident surface IN4 may be positive. The fourth light-emitting surface OT4 of the fourth lens LE21 may be a surface perpendicular to the third direction DR3. That is, the fourth light-emitting surface OT4 may be a surface parallel to the first direction DR1. The radius of curvature of the fourth light-emitting surface OT4 may correspond to infinity.

The output light (OTL, refer to FIG. 3) passed through the first to fourth lenses LE11, LE12, LE13, and LE21 may be output to the irradiation object TO. The energy intensity measured in the short axis direction (e.g., the first direction DR1) of the output light may have a super-Gaussian profile of greater than or equal to about 2.5 orders and less than or equal to about 7.5 orders.

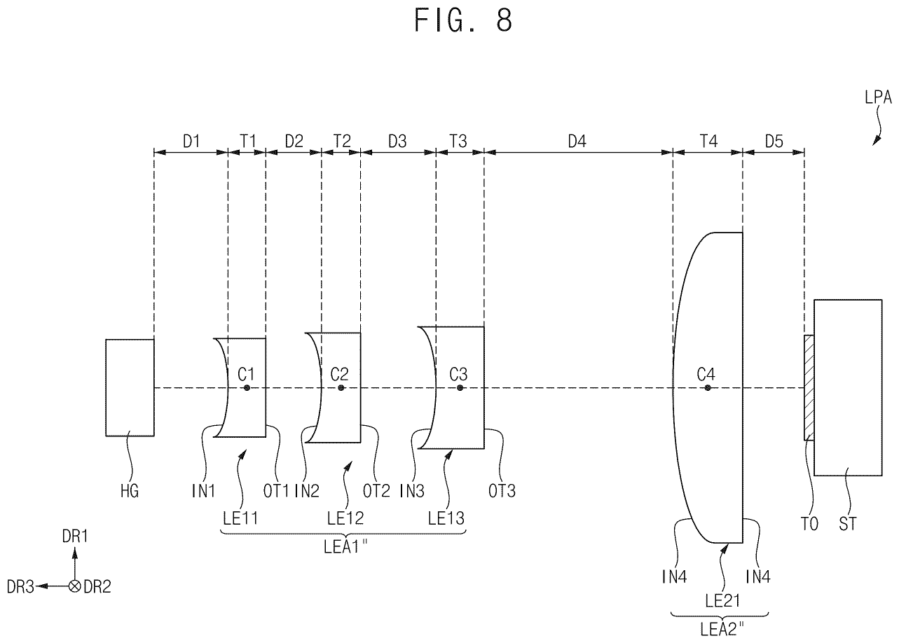

FIG. 8 is a view illustrating an embodiment of a first lens group and a second lens group included in the laser processing apparatus of FIG. 3.

Referring to FIG. 8, in an embodiment, the laser processing apparatus LPA may include the homogenizer HG, a first lens group LEA1″, and a second lens group LEA2″. Hereinafter, any repetitive detailed descriptions of the same or like features of the first lens group LEA1′ and the second lens group LEA2′ as those described above with reference to FIG. 7 will be omitted or simplified.

The first lens group LEA1″ may be arranged between the homogenizer HG and the second lens group LEA2″. In an embodiment, the first lens group LEA1″ may include at least two lenses. In an embodiment, for example, the first lens group LEA1″ may include a first lens LE11, a second lens LE12, and a third lens LE13.

The second lens group LEA2″ may be arranged between the first lens group LEA1″ and the irradiation object TO. In an embodiment, the second lens group LEA2″ may include only one lens. In an embodiment, for example, the second lens group LEA2″ may include a fourth lens LE21.

A first focal length of the first lens group LEA1″ may be greater than about −1000 millimeters and less than about −300 millimeters. In other words, a composite focal length of the first to third lenses LE11, LE12, and LE13 included in the first lens group LEA1″ may be greater than about −1000 millimeters and less than about −300 millimeters.

In an embodiment, each of the first lens LE11, the second lens LE12, and the third lens LE13 may have a negative refractive power. However, the present disclosure is not necessarily limited thereto.

A first light-incident surface IN1 of the first lens LE11 may face the homogenizer HG, and a first light-emitting surface OT1 of the first lens LE11 may face a second light-incident surface IN2 of the second lens LE12. The first light-incident surface IN1 may have a concave shape toward a first center C1. The radius of curvature of the first light-incident surface IN1 may be negative. The first light-emitting surface OT1 may be a surface parallel to the first direction DR1. The radius of curvature of the first light-emitting surface OT1 may correspond to infinity.

The second light-incident surface IN2 of the second lens LE12 may face the first light-emitting surface OT1, and a second light-emitting surface OT2 of the second lens LE12 may face a third light-incident surface IN3 of the third lens LE13. The second light-incident surface IN2 may have a concave shape toward a second center C2. The radius of curvature of the second light-incident surface IN2 may be negative. The second light-emitting surface OT2 may be a surface parallel to the first direction DR1. The radius of curvature of the second light-emitting surface OT2 may correspond to infinity.

The third light-incident surface IN3 of the third lens LE13 may face the second light-emitting surface OT2, and a third light-emitting surface OT3 of the third lens LE13 may face a fourth light-incident surface IN4 of the fourth lens LE21. The third light-incident surface IN3 may have a concave shape toward a third center C3. The radius of curvature of the third light-incident surface IN3 may be negative. The third light-emitting surface OT3 may be a surface parallel to the first direction DR1. The radius of curvature of the third light-emitting surface OT3 may correspond to infinity.

A distance between the first lens group LEA1″ and the second lens group LEA2″ may be greater than about 2000 millimeters and less than about 6000 millimeters. In other words, a fourth distance D4 between the third lens LE13 and the fourth lens LE21 may be greater than about 2000 millimeters and less than about 6000 millimeters.

A second focal length of the second lens group LEA2″ may be greater than about 100 millimeters and less than about 300 millimeters. In other words, a focal length of the fourth lens LE21 included in the second lens group LEA2″ may be greater than about 100 millimeters and less than about 300 millimeters.

The fourth lens LE21 may have a positive refractive power. The fourth light-incident surface IN4 of the fourth lens LE21 may face the third light-emitting surface OT3, and a fourth light-emitting surface OT4 of the fourth lens LE21 may face the irradiation object TO. The fourth light-incident surface IN4 may have a convex shape facing a fourth center C4. The radius of curvature of the fourth light-incident surface IN4 may be positive. The fourth light-emitting surface OT4 may be a surface parallel to the first direction DR1. The radius of curvature of the fourth light-emitting surface OT4 may correspond to infinity.

The output light (OTL, refer to FIG. 3) passed through the first to fourth lenses LE11, LE12, LE13, and LE21 may be output to the irradiation object TO. The energy intensity measured in the short axis direction (e.g., the first direction DR1) of the output light may have a super-Gaussian profile of greater than or equal to about 2.5 orders and less than or equal to about 7.5 orders.

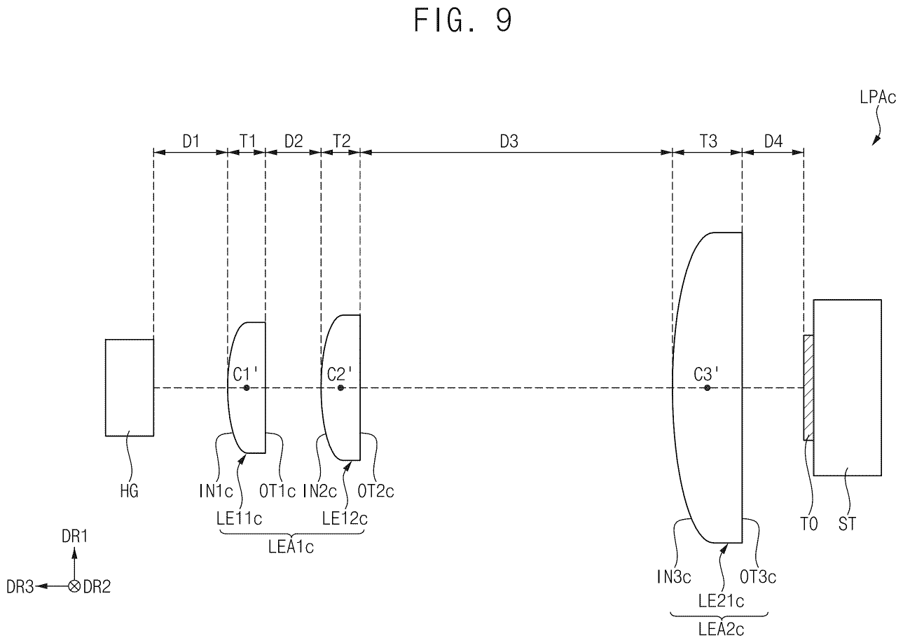

FIG. 9 is a view illustrating an example of a first lens group and a second lens group included in a laser processing apparatus according to a comparative example.

Referring to FIG. 9, a laser processing apparatus LPAc according to a comparative example may include a homogenizer HG, a first lens group LEA1c, and a second lens group LEA2c.

In the comparative example, the first lens group LEA1c may be arranged between the homogenizer HG and the second lens group LEA2c. For example, the first lens group LEA1c may include a first lens LE11c and a second lens LE12c.

In the comparative example, the second lens group LEA2c may be arranged between the first lens group LEA1c and the irradiation object TO. For example, the second lens group LEA2c may include a third lens LE21c.

Each of the first lens LE11c, the second lens LE12c, and the third lens LE21c may have a positive refractive power.

A first light-incident surface IN1c of the first lens LE11c may face the homogenizer HG, and a first light-emitting surface OT1c of the first lens LE11c may face a second light-incident surface IN2c of the second lens LE12c. The first light-incident surface IN1c may have a convex shape toward a first center C1′. The radius of curvature of the first light-incident surface IN1c may be positive. The first light-emitting surface OT1c may be a surface parallel to the first direction DR1. The radius of curvature of the first light-emitting surface OT1c may correspond to infinity.

The second light-incident surface IN2c of the second lens LE12c may face the first light-emitting surface OT1c, and a second light-emitting surface OT2c of the second lens LE12c may face a third light-incident surface IN3c of the third lens LE21c. The second light-incident surface IN2c may have a convex shape toward a second center C2′. The radius of curvature of the second light-incident surface IN2c may be positive. The second light-emitting surface OT2c may be a surface parallel to the first direction DR1. The radius of curvature of the second light-emitting surface OT2c may correspond to infinity.

The third light-incident surface IN3c of the third lens LE21c may face the second light-emitting surface OT2c, and a third light-emitting surface OT3c of the third lens LE21c may face the irradiation object TO. The third light-incident surface IN3c may have a convex shape toward a third center C3′. The radius of curvature of the third light-incident surface IN3c may be positive. The third light-emitting surface OT3c may be a surface parallel to the first direction DR1. The radius of curvature of the third light-emitting surface OT3c may correspond to infinity.

An output light passed through the first to third lenses LE11c, LE12c, and LE21c may be output to the irradiation object TO. In the comparative example, the energy intensity measured in the short axis direction (e.g., the first direction DR1) of the output light may have a super-Gaussian profile of less than about 2.5 orders.

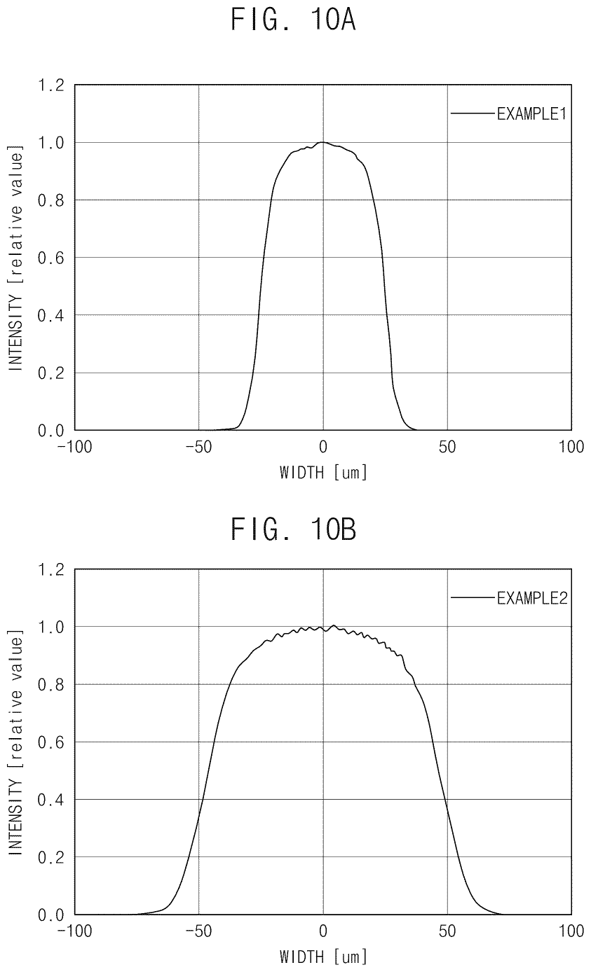

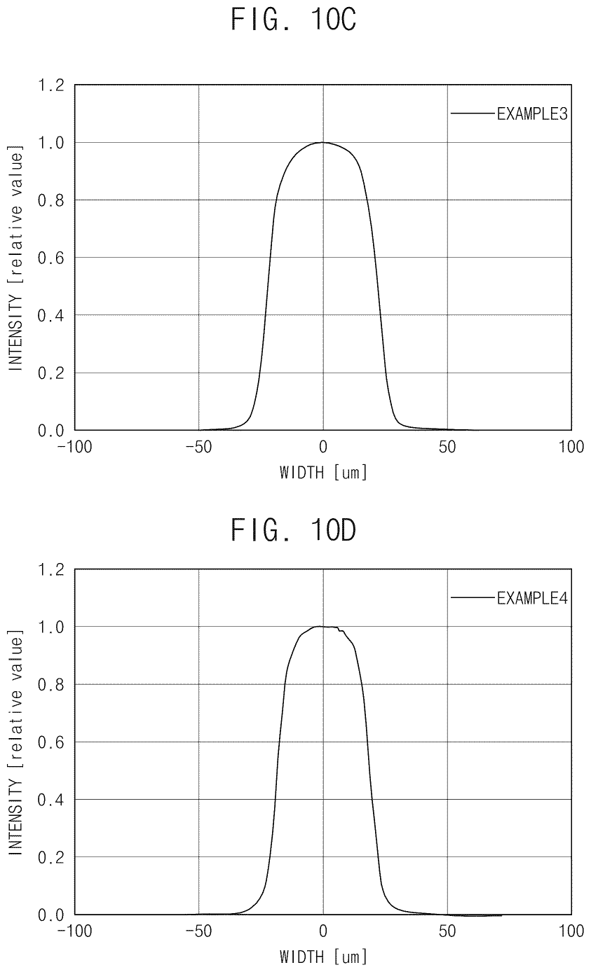

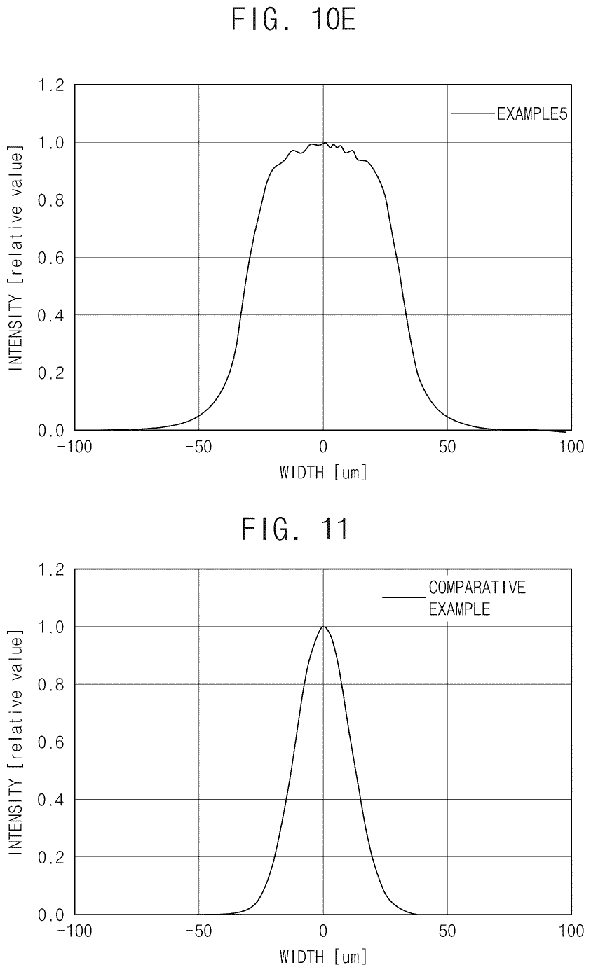

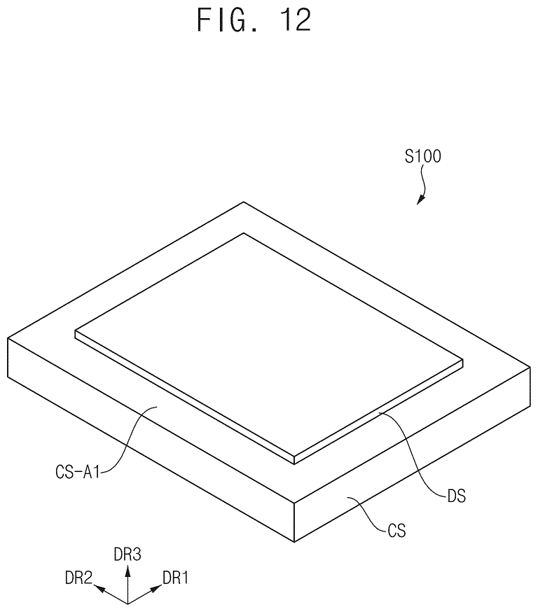

FIGS. 10A, 10B, 10C, 10D, and 10E are diagrams illustrating an intensity profile of an output light emitted from a laser processing apparatus according to embodiments of the present disclosure. FIG. 11 is a diagram illustrating an intensity profile of an output light emitted from a laser processing apparatus according to a comparative example.

Hereinafter, the effects of the present disclosure will be described with reference to FIGS. 7, 8, 9, 10A, 10B, 10C, 10D, 10E, and 11.

The intensity of the output light emitted by laser processing apparatuses corresponding to (satisfying conditions of) Comparative Example, Embodiment 1 (EXAMPL1), Embodiment 2 (EXAMPL2), Embodiment 3 (EXAMPL3), Embodiment 4 (EXAMPL4), and Embodiment 5 (EXAMPL5) was measured. Here, the intensity of the output light means the intensity in the short axis direction of the output light. The depth of focus (DOF) of the output light emitted by the laser processing apparatuses satisfying Comparative Example, Embodiment 1, Embodiment 2, Embodiment 3, Embodiment 4, and Embodiment 5 is about 200 mm.

Each of the laser processing apparatuses (e.g., the laser processing apparatus LPA of FIG. 7) corresponding to the Embodiment 1 and the Embodiment 2 includes a homogenizer HG, a first lens group LEA1′, and a second lens group LEA2′. The first lens group LEA1′ includes a first lens LE11, a second lens LE12, and a third lens LE13. The second lens group LEA2′ includes a fourth lens LE21. Each of the first lens LE11 and the third lens LE13 has a negative refractive power, and each of the second lens LE12 and the fourth lens LE21 has a positive refractive power. The refractive index of each of the first to fourth lenses LE11, LE12, LE13, and LE21 is about 1.478. A first thickness T1 of the first lens LE11 is about 10 millimeters (mm). A second thickness T2 of the second lens LE12 is about 10 mm. A third thickness T3 of the third lens LE13 is about 15 mm. A fourth thickness T4 of the fourth lens LE21 is about 20 mm.

In the laser processing apparatus corresponding to the Example 1, a first distance D1 between the homogenizer HG and the first lens LE11 is about 238 mm. A second distance D2 between the first lens LElb and the second lens LE12 is about 195.5 mm. A third distance D3 between the second lens LE12 and the third lens LE13 is about 490 mm. A distance between the first lens group LEA1′ and the second lens group LEA2′ is about 4025 mm. That is, a fourth distance D4 between the third lens LE13 and the fourth lens LE21 is about 4025 mm. A fifth distance D5 between the fourth lens LE21 and the irradiation object TO is about 224.7 mm.

In the laser processing apparatus corresponding to the Example 1, a focal length of the first lens group LEA1′ is about −613 mm. That is, a composite focal length ofthe firstto third lenses LE11, LE12, and LE13 is about −613 mm. A focal length of the second lens group LEA2′ is about 209 mm. That is, a focal length of the fourth lens LE21 is about 209 mm. The specifications of the first to fourth lenses LE11, LE12, LED3, and LE21 of Embodiment 1 are shown in Table 1 below.

TABLE 1
Embodiment 1

| | | radius of | | | focal |
|---|---|---|---|---|---|
| | | curvature | thickness | refractive | length |
| Lens | surface | (mm) | (mm) | index | (mm) |
| first lens | IN1 | −600 | 10 | 1.478 | −613 |
| LE11 | OT1 | +1200 | | | |
| second lens | IN2 | +2400 | 10 | 1.478 | |
| LE12 | OT2 | ∞ | | | |
| third lens | IN3 | −1200 | 15 | 1.478 | |
| LE13 | OT3 | ∞ | | | |
| fourth lens | IN4 | +100 | 20 | 1.478 | +209 |
| LE21 | OT4 | ∞ | | | |

In the laser processing apparatus corresponding to the Embodiment 2, a first distance D1 between the homogenizer HG and the first lens LE11 is about 238 mm. A second distance D2 between the first lens LE11 and the second lens LE12 is about 195.5 mm. A third distance D3 between the second lens LE12 and the third lens LE13 is about 490 mm. A distance between the first lens group LEA1′ and the second lens group LEA2′ is about 2100 mm. That is, a fourth distance D4 between the third lens LE13 and the fourth lens LE21 is about 2100 mm. A fifth distance D5 between the fourth lens LE21 and the irradiation object TO is about 332.5 mm.

In the laser processing apparatus corresponding to the Embodiment 2, a focal length of the first lens group LEA1′ is about −416 mm. That is, a composite focal length of the first to third lenses LE11, LE12, and LE13 is about −416 mm. A focal length of the second lens group LEA2′ is about 293 mm. That is, a focal length of the fourth lens LE21 is about 293 mm. The specifications of the first to fourth lenses LE11, LE12, LE13, and LE21 of the Embodiment 2 are shown in Table 2 below.

TABLE 2
Embodiment 2

| | | radius of | | | focal |
|---|---|---|---|---|---|
| | | curvature | thickness | refractive | length |
| Lens | surface | (mm) | (mm) | index | (mm) |
| first lens | IN1 | −600 | 10 | 1.478 | −416 |
| LE11 | OT1 | +600 | | | |
| second lens | IN2 | +1000 | 10 | 1.478 | |
| LE12 | OT2 | ∞ | | | |
| third lens | IN3 | −600 | 15 | 1.478 | |
| LE13 | OT3 | ∞ | | | |
| fourth lens | IN4 | +140 | 20 | 1.478 | +293 |
| LE21 | OT4 | ∞ | | | |

Each of the laser processing apparatuses (e.g., the laser processing apparatus LPA of FIG. 8) corresponding to the Embodiment 3, the Embodiment 4, and the Embodiment 5 includes a homogenizer HG, a first lens group LEA1″, and a second lens group LEA2″. The first lens group LEA1″ includes a first lens LE11, a second lens LE12, and a third lens LE13. The second lens group LEA2″ includes a fourth lens LE21. Each of the first lens LE11, the second lens LE12, and the third lens LE13 has a negative refractive power, and the fourth lens LE21 has a positive refractive power. The refractive index of each of the first to fourth lenses LE11, LE12, LE13, and LE21 is about 1.478. A first thickness T1 of the first lens LE11 is about 10 mm. A second thickness T2 of the second lens LE12 is about 10 mm. A third thickness T3 of the third lens LE13 is about 15 mm. A fourth thickness T4 of the fourth lens LE21 is about 20 mm.

In the laser processing apparatus corresponding to the Embodiment 3, a first distance D1 between the homogenizer HG and the first lens LE11 is about 238 mm. A second distance D2 between the first lens LE11 and the second lens LE12 is about 195.5 mm. A third distance D3 between the second lens LE12 and the third lens LE13 is about 490 mm. A distance between the first lens group LEA1″ and the second lens group LEA2″ is about 5800 mm. That is, a fourth distance D4 between the third lens LE13 and the fourth lens LE21 is about 5800 mm. A fifth distance D5 between the fourth lens LE21 and the irradiation object TO is about 312.6 mm.

In the laser processing apparatus corresponding to the Embodiment 3, a focal length of the first lens group LEA1″ is about −929 mm. That is, a composite focal length of the first to third lenses LE11, LE12, and LE13 is about −929 mm. A focal length of the second lens group LEA2″ is about 293 mm. That is, a focal length of the fourth lens LE21 is about 293 mm. The specifications of the first to fourth lenses LE20, LE12, LE13, and LE21 of the Embodiment 3 are shown in Table 3 below.

TABLE 3
Embodiment 3

| | | radius of | | | focal |
|---|---|---|---|---|---|
| | | curvature | thickness | refractive | length |
| Lens | surface | (mm) | (mm) | index | (mm) |
| first lens | IN1 | −1500 | 10 | 1.478 | −929 |
| LE11 | OT1 | ∞ | | | |
| second lens | IN2 | −1600 | 10 | 1.478 | |
| LE12 | OT2 | ∞ | | | |
| third lens | IN3 | −1500 | 15 | 1.478 | |
| LE13 | OT3 | ∞ | | | |
| fourth lens | IN4 | +140 | 20 | 1.478 | +293 |
| LE21 | OT4 | ∞ | | | |

In the laser processing apparatus corresponding to the Embodiment 4, a first distance D1 between the homogenizer HG and the first lens LE11 is about 238 mm. A second distance D2 between the first lens LE11 and the second lens LE12 is about 195.5 mm. A third distance D3 between the second lens LE12 and the third lens LE13 is about 490 mm. A distance between the first lens group LEA1″ and the second lens group LEA2″ is about 5800 mm. That is, a fourth distance D4 between the third lens LE13 and the fourth lens LE21 is about 5800 mm. A fifth distance D5 between the fourth lens LE21 and the irradiation object TO is about 114.9 mm.

In the laser processing apparatus corresponding to the Embodiment 4, a focal length of the first lens group LEA1″ is about −929 mm. That is, a composite focal length of the first to third lenses LE11, LE12, and LE13 is about −929 mm. A focal length of the second lens group LEA2″ is about 105 mm. That is, a focal length of the fourth lens LE21 is about 105 mm. The specifications of the first to fourth lenses LE11, LE12, LE13, and LE21 of the Embodiment 4 are shown in Table 4 below.

TABLE 4
Embodiment 4

| | | radius of | | | focal |
|---|---|---|---|---|---|
| | | curvature | thickness | refractive | length |
| Lens | surface | (mm) | (mm) | index | (mm) |
| first lens | IN1 | −1500 | 10 | 1.478 | −929 |
| LE11 | OT1 | ∞ | | | |
| second lens | IN2 | −1600 | 10 | 1.478 | |
| LE12 | OT2 | ∞ | | | |
| third lens | IN3 | −1500 | 15 | 1.478 | |
| LE13 | OT3 | ∞ | | | |
| fourth lens | IN4 | +50 | 20 | 1.478 | +105 |
| LE21 | OT4 | ∞ | | | |

In the laser processing apparatus corresponding to the Embodiment 5, a first distance D1 between the homogenizer HG and the first lens LE11 is about 238 mm. A second distance D2 between the first lens LE11 and the second lens LE12 is about 195.5 mm. A third distance D3 between the second lens LE12 and the third lens LE13 is about 490 mm. A distance between the first lens group LEA1″ and the second lens group LEA2″ is about 3000 mm. That is, a fourth distance D4 between the third lens LE13 and the fourth lens LE21 is about 3000 mm. A fifth distance D5 between the fourth lens LE21 and the irradiation object TO is about 334.1 mm.

In the laser processing apparatus corresponding to the Embodiment 5, a focal length of the first lens group LEA1″ is about −305 mm. That is, a composite focal length of the first to third lenses LE11, LE12, and LE13 is about −305 mm. A focal length of the second lens group LEA2″ is about 293 mm. That is, a focal length of the fourth lens LE21 is about 293 mm. The specifications of the first to fourth lenses LE11, LE12, LE13, and LE21 of the Embodiment 5 are shown in Table 5 below.

TABLE 5
Embodiment 5

| | | radius of | | | focal |
|---|---|---|---|---|---|
| | | curvature | thickness | refractive | length |
| Lens | surface | (mm) | (mm) | index | (mm) |
| first lens | IN1 | −600 | 10 | 1.478 | −305 |
| LE11 | OT1 | ∞ | | | |
| second lens | IN2 | −600 | 10 | 1.478 | |
| LE12 | OT2 | ∞ | | | |
| third lens | IN3 | −620 | 15 | 1.478 | |
| LE13 | OT3 | ∞ | | | |
| fourth lens | IN4 | +140 | 20 | 1.478 | +293 |
| LE21 | OT4 | ∞ | | | |

The laser processing apparatus (e.g., the laser processing apparatus LPAc of FIG. 9) corresponding to the Comparative Example includes a homogenizer HG, a first lens group LEA1c, and a second lens group LEA2c. The first lens group LEA1c includes a first lens LE11c and a second lens LE12c. The second lens group LEA2c includes a third lens LE21c. Each of the first lens LE11c, the second lens LE12c, and the third lens LE21c has a positive refractive power. The refractive index of each of the first to third lenses LE11c, LE12c, and LE21c is about 1.478. A first thickness T1 of the first lens LE11c is about 10 mm. A second thickness T2 of the second lens LE12c is about 10 mm. A third thickness T3 of the third lens LE21c is about 20 mm.

In the laser processing apparatus corresponding to the Comparative Example, a first distance D1 between the homogenizer HG and the first lens LE11c is about 238 mm. A second distance D2 between the first lens LE11c and the second lens LE12c is about 195.5 mm. A distance between the first lens group LEA1c and the second lens group LEA2c is about 4530 mm. That is, a third distance D3 between the second lens LE12c and the third lens LE21c is about 4530 mm. A fourth distance D4 between the third lens LE21c and the irradiation object TO is about 226 mm.

In the laser processing apparatus corresponding to the Comparative Example, a focal length of the first lens group LEA1c is about 1520 mm. That is, a composite focal length of the first lens LE11c and the second lens LE12c is about 1520 mm. A focal length of the second lens group LEA2c is about 209 mm. That is, a focal length of the third lens LE21c is about 209 mm. The specifications of the first to third lenses LE11c, LE12c, and LE21c of the Comparative Example are shown in Table 6 below.

TABLE 6
Comparative Example

| | | radius of | | | focal |
|---|---|---|---|---|---|
| | | curvature | thickness | refractive | length |
| Lens | surface | (mm) | (mm) | index | (mm) |
| first lens | IN1c | +1000 | 10 | 1.478 | +1520 |
| LE11c | OT1c | ∞ | | | |
| second lens | IN2c | +2400 | 10 | 1.478 | |
| LE12c | OT2c | ∞ | | | |
| third lens | IN3c | +100 | 20 | 1.478 | +209 |
| LE21c | OT3c | ∞ | | | |

As a result, as illustrated in FIG. 10A, the energy intensity of the output light emitted from the laser processing apparatus corresponding to the Embodiment 1 was measured to have a super-Gaussian profile of about 5.2 orders to about 5.6 orders.

As illustrated in FIG. 10B, the energy intensity of the output light emitted from the laser processing apparatus corresponding to the Embodiment 2 was measured to have a super-Gaussian profile of about 4.4 orders to about 4.8 orders.

As illustrated in FIG. 10C, the energy intensity of the output light emitted from the laser processing apparatus corresponding to the Embodiment 3 was measured to have a super-Gaussian profile of about 5.3 orders.

As illustrated in FIG. 10D, the energy intensity of the output light emitted from the laser processing apparatus corresponding to the Embodiment 4 was measured to have a super-Gaussian profile of about 4.8 orders to about 5.1 orders.

As illustrated in FIG. 10E, the energy intensity of the output light emitted from the laser processing apparatus corresponding to the Embodiment 5 was measured to have a super-Gaussian profile of about 4.2 orders.

As illustrated in FIG. 11, the energy intensity of the output light emitted from the laser processing apparatus corresponding to the Comparative Example was measured to have a super-Gaussian profile of about 2.0 orders.

From these results, the energy intensity of the output light emitted by the laser processing apparatus LPA according to the embodiments of the present disclosure may have a super-Gaussian profile of greater than or equal to about 2.5 orders and less than or equal to about 7.5 orders. Accordingly, the output light may process the irradiation object TO without excessively exceeding the processing threshold (ATH, refer to FIG. 6) with relatively uniform energy intensity, and damage to the irradiation object TO may be minimized.

FIGS. 12, 13, 14, 15, 16, and 17 are views illustrating a method of manufacturing a display device according to an embodiment of the present disclosure.

Referring to FIG. 12, in an embodiment of a method of manufacturing a display device, a display substrate DS may be formed on a first surface CS-A1 of a carrier substrate CS (S100).

The carrier substrate CS may include a rigid substrate to serve as a support in the manufacturing process of a display device. The carrier substrate CS may include a transparent material so that a laser may pass through in a subsequent peeling process. In an embodiment, for example, the carrier substrate CS may include a quartz substrate (e.g., a synthetic quartz substrate, a fluorine-doped quartz substrate, or the like), a soda-lime glass substrate, a non-alkali glass substrate, or the like. These may be used alone or in combination with each other.

The display substrate DS may be formed on the first surface CS-A1 of the carrier substrate CS. The display substrate DS may include a transparent material or an opaque material. The display substrate DS may include a quartz substrate (e.g., a synthetic quartz substrate, a fluorine-doped quartz substrate, or the like), a soda-lime glass substrate, a non-alkali glass substrate, or the like. These may be used alone or in combination with each other.

In an embodiment, the display substrate DS may include a flexible substrate. A polyimide substrate may be an example of the flexible substrate. The polyimide substrate may include a first organic layer, a first barrier layer, a second organic layer, a second barrier layer, or the like.

Referring to FIGS. 13 and 14, in an embodiment of a method of manufacturing a display device, a light-emitting element LD may be formed on the display substrate DS (S200). In an embodiment, for example, a display element layer DPL including the light-emitting element LD, and an encapsulation layer TFE arranged on the display element layer DPL may be formed on the display substrate DS. Accordingly, a display device DD including the display substrate DS, the display element layer DPL, and the encapsulation layer TFE may be formed.

In an embodiment of a method of manufacturing a display device, As illustrated in FIG. 14, the display element layer DPL may include a transistor TFT, a gate insulating layer GI, an inter-layer insulating layer ILD, a via-insulating layer VIA, the light-emitting element LD, and a pixel defining layer PDL. The transistor TFT may include an active pattern ACT, a gate electrode GE, a source electrode SE, and a drain electrode DE. The light-emitting element LD may include a pixel electrode PE, a light-emitting layer EML, and a common electrode CE.

The active pattern ACT may be formed on the display substrate DS. The active pattern ACT may include a silicon semiconductor, an oxide semiconductor, an organic semiconductors, or the like. In an embodiment, for example, the silicon semiconductor may include amorphous silicon, polycrystalline silicon, or the like. In an embodiment, for example, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), and zinc (Zn), or the like. The active pattern ACT may include a source area, a drain area, and a channel area between the source area and the drain area.

The gate insulating layer GI may be formed on the display substrate DS. In an embodiment, for example, the gate insulating layer GI may cover the active pattern ACT on the display substrate DS and may be formed along the profile of the active pattern ACT with a substantially uniform thickness. The gate insulating layer GI may include an inorganic insulating material. Examples of the inorganic insulating material that may be used as the gate insulating layer GI include silicon oxide (SiOₓ), silicon nitride (SiNₓ), silicon oxynitride (SiOₓN_{y}), or the like. These may be used alone or in combination with each other.

The gate electrode GE may be formed on the gate insulating layer GI. The gate electrode GE may overlap the channel area of the active pattern ACT in a third direction DR3, which is a thickness direction of the display substrate DS. The gate electrode GE may include a conductive material such as a metal, an alloy, a conductive metal nitride, a conductive metal oxide, a transparent conductive oxide, or the like. Examples of the conductive material that may be used as the gate electrode GE may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other.

The inter-layer insulating layer ILD may be formed on the gate insulating layer GI. In an embodiment, for example, the inter-layer insulating layer ILD may cover the gate electrode GE on the gate insulating layer GI and may be formed along the profile of the gate electrode GE with a substantially uniform thickness. The inter-layer insulating layer ILD may include an inorganic insulating material. Examples of the inorganic insulating material that may be used as the inter-layer insulating layer ILD may include silicon oxide (SiOₓ), silicon nitride (SiNₓ), silicon oxynitride (SiOₓN_{y}), or the like. These may be used alone or in combination with each other.

The source electrode SE and the drain electrode DE may be formed on the inter-layer insulating layer ILD. The source electrode SE may be connected to the source area of the active pattern ACT through a contact hole that penetrates (or is defined or formed through) the gate insulating layer GI and the inter-layer insulating layer ILD. The drain electrode DE may be connected to the drain area of the active pattern ACT through a contact hole that penetrates the gate insulating layer GI and the inter-layer insulating layer ILD. Each of the source electrode SE and the drain electrode DE may include a conductive material such as a metal, an alloy, a conductive metal nitride, a conductive metal oxide, a transparent conductive oxide, or the like. These may be used alone or in combination with each other.

Accordingly, the transistor TFT including the active pattern ACT, the gate electrode GE, the source electrode SE, and the drain electrode DE may be formed on the display substrate DS.

The via-insulating layer VIA may be formed on the inter-layer insulating layer ILD. In an embodiment, for example, the via-insulating layer VIA may be arranged with a relatively thick thickness to sufficiently cover the source electrode SE and the drain electrode DE on the inter-layer insulating layer ILD. In an embodiment, for example, the via-insulating layer VIA may have a flat upper surface. The via-insulating layer VIA may include an organic insulating material. Examples of the organic insulating material that may be used as the via-insulating layer VIA may include a polyacryl-based resin, a polyimide-based resin, a polyamide-based resin, a siloxane-based resin, an acryl-based resin, an epoxy-based resin, or the like. These may be used alone or in combination with each other.

The pixel electrode PE may be formed on the via-insulating layer VIA. The pixel electrode PE may be connected to the source electrode SE or the drain electrode DE through a contact hole that penetrates the via-insulating layer VIA. Accordingly, the pixel electrode PE may be electrically connected to the transistor TFT. The pixel electrode PE may include a conductive material such as a metal, an alloy, a conductive metal nitride, a conductive metal oxide, a transparent conductive oxide, or the like. These may be used alone or in combination with each other. In an embodiment, for example, the pixel electrode PE may function as an anode.

The pixel defining layer PDL may be formed on the via-insulating layer VIA. The pixel defining layer PDL may cover an edge of the pixel electrode PE and may expose an upper surface of the pixel electrode PE. The pixel defining layer PDL may include an organic insulating material and/or an inorganic insulating material. Examples of the organic insulating material that may be used as the pixel defining layer PDL may include a polyacryl-based resin, a polyimide-based resin, a polyamide-based resin, a siloxane-based resin, an acryl-based resin, an epoxy-based resin, or the like. These may be used alone or in combination with each other.

The light-emitting layer EML may be formed on the pixel electrode PE. The light-emitting layer EML may include materials for emitting light. In an embodiment, for example, the light-emitting layer EML may include at least one of an organic light-emitting material and a quantum dot.

The common electrode CE may be formed on the pixel defining layer PDL and the light-emitting layer EML. The common electrode CE may cover the pixel defining layer PDL and the light-emitting layer EML and may be formed along the profiles of the pixel defining layer PDL and the light-emitting layer EML with a substantially uniform thickness. The common electrode CE may include a conductive material such as a metal, an alloy, a conductive metal nitride, a conductive metal oxide, a transparent conductive oxide, or the like. These may be used alone or in combination with each other. In an embodiment, for example, the common electrode CE may function as a cathode.

Accordingly, the light-emitting element LD including the pixel electrode PE, the light-emitting layer EML, and the common electrode CE may be formed on the via-insulating layer VIA.

The encapsulation layer TFE may be formed on the common electrode CE. The encapsulation layer TFE may prevent impurities, moisture, or the like from penetrating into the light-emitting element LD from the outside. The encapsulation layer TFE may include at least one inorganic encapsulation layer and at least one organic encapsulation layer. In an embodiment, for example, the inorganic encapsulation layer may include silicon oxide (SiOₓ), silicon nitride (SiNₓ), silicon oxynitride (SiOₓN_{y}), or the like. These may be used alone or in combination with each other. In an embodiment, for example, the organic encapsulation layer may include a polymer cured material such as a polyacrylate.

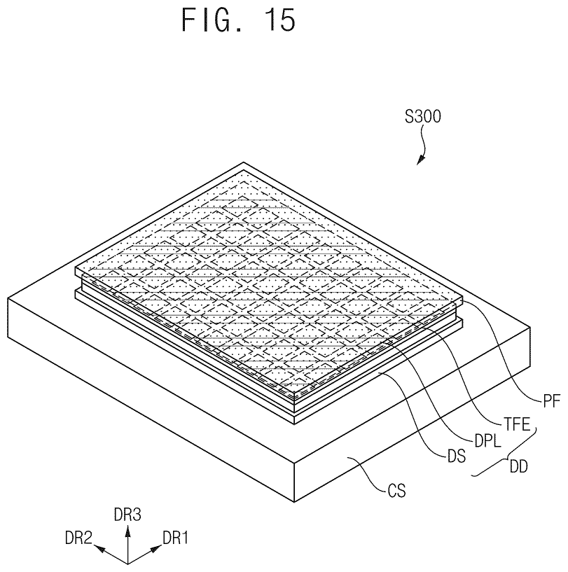

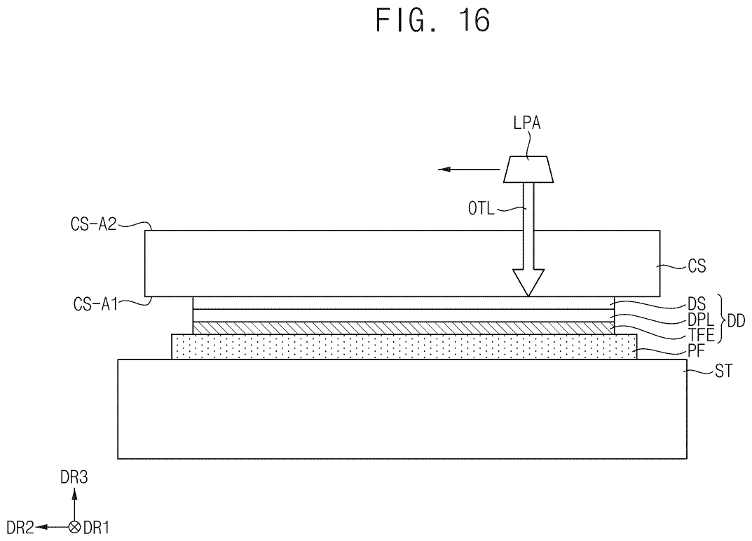

Referring to FIG. 15, in an embodiment of a method of manufacturing a display device, a protective film PF may be formed on the encapsulation layer TFE (S300). The protective film PF may prevent the encapsulation layer TFE from being damaged during a subsequent process of peeling and removing the carrier substrate CS. After removing the carrier substrate CS, the protective film PF may be removed.

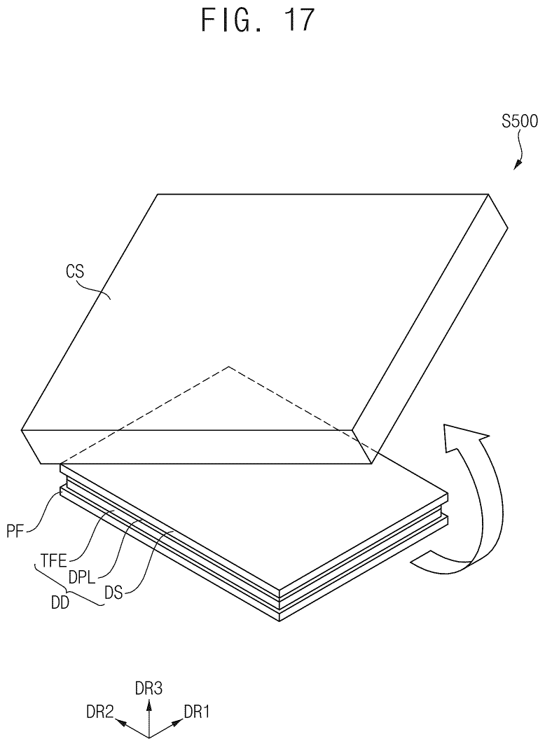

Referring to FIG. 16, in an embodiment of a method of manufacturing a display device, the carrier substrate CS can be peeled off by radiating output light OTL to a second surface CS-A2 opposite to the first surface CS-A1 of the carrier substrate CS (S400).

A laser processing apparatus LPA may move in the second direction DR2 and may radiate the output light OTL to the second surface CS-A2 of the carrier substrate CS. In an embodiment, for example, the laser processing apparatus LPA may radiate the output light OTL having energy capable of breaking the bond between the carrier substrate CS and the display substrate DS.

As described above with reference to FIGS. 3 to 6, the laser processing apparatus LPA may include the laser irradiation part LSP and the optical system OS, and the optical system OS may include the homogenizer HG, the first lens group LEA1, and the second lens group LEA2. A first focal length of the first lens group LEA1 may be greater than about −1000 millimeters and less than about −300 millimeters, and a second focal length of the second lens group LEA2 may be greater than about 100 millimeters and less than about 300 millimeters, and a distance between the first lens group LEA1 and the second lens group LEA2 may be greater than about 2000 millimeters and less than about 6000 millimeters.

The solid laser beams SOL radiated from the laser irradiation part LSP may be converted into the output light OTL by passing through the optical system OS. The output light OTL converted by the optical system OS may be a Gaussian beam having a super-Gaussian profile. In an embodiment, the energy intensity measured in the short axis direction of the output light OTL may have a super-Gaussian profile of greater than or equal to about 2.5 orders and less than or equal to about 7.5 orders. Accordingly, the output light OTL may peel off the carrier substrate CS from the display substrate DS with a relatively uniform energy intensity without excessively exceeding the processing threshold (ATH, refer to FIG. 6). Accordingly, in a process of peeling the carrier substrate CS using the output light OTL, damage to the display substrate DS may be minimized. That is, the reliability of a process of peeling the carrier substrate CS may be improved.

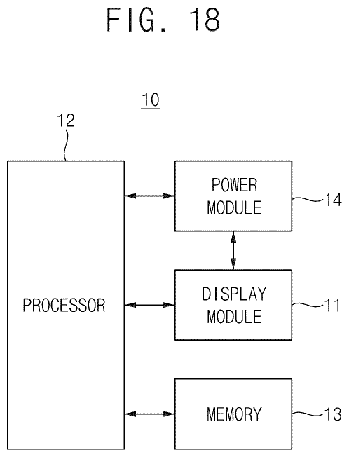

Referring to FIG. 17, in an embodiment of a method of manufacturing a display device, after the carrier substrate CS is peeled off, the carrier substrate CS may be removed (S500). Various known methods in the art may be used to remove the carrier substrate CS. After the carrier substrate CS is removed, the protective film PF formed on the encapsulation layer TFE may be removed.

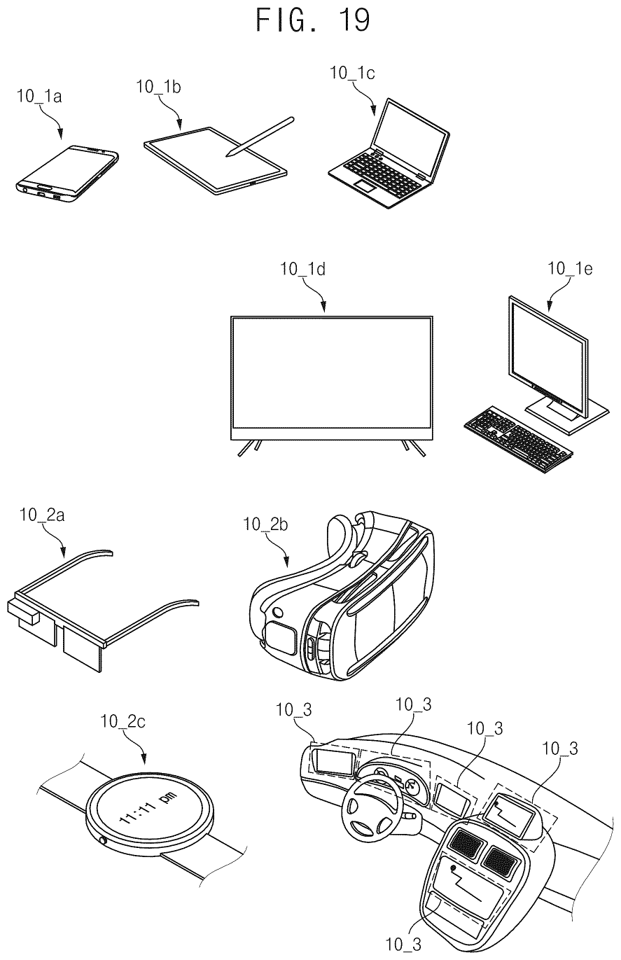

FIG. 18 is a block diagram of an electronic device according to an embodiment of the present disclosure.

Referring to FIG. 18, an electronic device 10 according to an embodiment may include a display module 11, a processor 12, a memory 13, and a power module 14. The display device (DD, refer to FIG. 17) according to an embodiment may be applied to a variety of electronic devices. The electronic device 10 according to an embodiment may include the display device described above, and may further include modules or devices having other additional functions in addition to the display device.

The processor 12 may include at least one selected from a central processing unit (CPU), an application processor (AP), a graphic processing unit (GPU), a communication processor (CP), an image signal processor (ISP), and a controller.

The memory 13 may store data information for operation of the processor 12 or the display module 11. When the processor 12 executes an application stored in the memory 13, an image data signal and/or an input control signal may be transmitted to the display module 11, and the display module 11 may process the received signals and may output image information through a display screen.

The power module 14 may include a power supply module, such as a power adapter or a battery device, etc., and a power conversion module that converts power supplied by the power supply module to generate the power for operation of the electronic device 10. That is, the power module 14 may provide power to the display device according to an embodiment described above.

At least one of the components of the electronic device 10 described above may be included in the display device according to the embodiments described above. In addition, some of the individual modules that are functionally included in one module may be included in the display device and others may be provided separately from the display device. In an embodiment, for example, the display device may include the display module 11, and the processor 12, the memory 13, and the power module 14 may be provided in the form of other devices in the electronic device 10 other than the display device.

FIG. 19 is a schematic view of an electronic device according to various embodiments.

Referring to FIG. 19, various electronic devices to which a display device according to the embodiments is applied may include image display electronic devices such as a smartphones 10_1a, a tablet personal computer (PC) 10_1b, a laptop computer 10_1c, a television 10_1d, a desk monitor 10_1e, or the like, wearable electronic devices including display modules such as a smart glasses 10_2a, a head-mounted display 10_2b, and a smart watch 10_2c, or the like, and vehicle electronic devices 103 including display modules such as a center information display (CID) which may be disposed on a instrument panel, a center fascia, and a dashboard of an automobile and a room mirror display, or the like.

Embodiments of the present disclosure may be applied to various display devices. For example, the present disclosure is applicable to various display devices such as display devices for vehicles, ships and aircraft, portable communication devices, display devices for exhibition or information transmission, medical display devices, and the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A laser processing apparatus, the apparatus comprising:
a laser irradiation part which radiates solid laser beams;
a homogenizer which homogenizes the solid laser beams;
a first lens group which receives a first light passed through the homogenizer, has a negative focal length of greater than about −1000 millimeters and less than about −300 millimeters, and outputs a second light different from the first light; and
a second lens group which receives the second light passed through the first lens group, has a positive focal length of greater than about 100 millimeters and less than about 300 millimeters, and outputs an output light to an irradiation object,
wherein an energy intensity of the output light has a super-Gaussian profile of greater than or equal to about 2.5 orders and less than or equal to about 7.5 orders.

2. The apparatus of claim 1, wherein a distance between the first lens group and the second lens group is greater than about 2000 millimeters and less than about 6000 millimeters.

3. The apparatus of claim 1,
wherein the irradiation object comprises a first side extending in a first direction and a second side contacting the first side and extending in a second direction intersecting the first direction,
wherein a length of the second side is greater than a length of the first side, and
wherein the energy intensity of the output light measured in the first direction has the super-Gaussian profile of greater than or equal to about 2.5 orders and less than or equal to about 7.5 orders.

4. The apparatus of claim 3, wherein the energy intensity of the output light measured in the first direction has a super-Gaussian profile of greater than or equal to about 4.0 orders and less than or equal to about 7.5 orders.

5. The apparatus of claim 1,
wherein the first lens group comprises a first lens, a second lens, and a third lens, and the second lens group comprises a fourth lens,
wherein the first to fourth lenses are sequentially arranged along a direction parallel to an optical axis of light traveling toward the irradiation object,
wherein a composite focal length of the first lens, the second lens, and the third lens is greater than about −1000 millimeters and less than about −300 millimeters, and
wherein a focal length of the fourth lens is greater than about 100 millimeters and less than about 300 millimeters.

6. The apparatus of claim 5,
wherein each of the first lens and the third lens has a negative refractive power, and
wherein each of the second lens and the fourth lens has a positive refractive power.

7. The apparatus of claim 5,
wherein each of a first light-incident surface of the first lens and a third light-incident surface of the third lens has a negative radius of curvature, and
wherein each of a second light-incident surface of the second lens and a fourth light-incident surface of the fourth lens has a positive radius of curvature.

8. The apparatus of claim 5,
wherein each of the first lens, the second lens, and the third lens has a negative refractive power, and
wherein the fourth lens has a positive refractive power.

9. The apparatus of claim 5,
wherein each of a first light-incident surface of the first lens, a second light-incident surface of the second lens, and a third light-incident surface of the third lens has a negative radius of curvature, and
wherein a fourth light-incident surface of the fourth lens has a positive radius of curvature.

10. The apparatus of claim 1, further comprising:
a shaping lens arranged between the laser irradiation part and the homogenizer,
wherein the shaping lens transforms an initial shape of the solid laser beams into a laser having a first shape.

11. The apparatus of claim 10, wherein the homogenizer rotates the laser having the first shape and transforms the laser having the first shape into a laser having a rotated shape of the first shape.

12. A method of manufacturing a display device, the method comprising:
providing a laser processing apparatus comprising a laser irradiation part which radiates solid laser beams, a homogenizer which homogenizes the solid laser beams, a first lens group which receives a light passed through the homogenizer and has a negative focal length of greater than about −1000 millimeters and less than about −300 millimeters, and a second lens group which receives a light passed through the first lens group and has a positive focal length of greater than about 100 millimeters and less than about 300 millimeters;
forming a display substrate on a first surface of a carrier substrate;
forming a light-emitting element on the display substrate; and
peeling off the carrier substrate from the display substrate by radiating output light of the laser processing apparatus to a second surface, which is opposite to the first surface, of the carrier substrate using the laser processing apparatus,
wherein an energy intensity of the output light has a super-Gaussian profile of greater than or equal to about 2.5 orders and less than or equal to about 7.5 orders.

13. The method of claim 12, wherein a distance between the first lens group and the second lens group is greater than about 2000 millimeters and less than about 6000 millimeters.

14. The method of claim 12,
wherein the display substrate comprises a first side extending in a first direction and a second side contacting the first side and extending in a second direction intersecting the first direction,
wherein a length of the second side is greater than a length of the first side, and
wherein the energy intensity of the output light measured in the first direction has the super-Gaussian profile of greater than or equal to about 2.5 orders and less than or equal to about 7.5 orders.

15. The method of claim 14, wherein the energy intensity of the output light measured in the first direction has a super-Gaussian profile of greater than or equal to about 4.0 orders and less than or equal to about 7.5 orders.

16. The method of claim 14, wherein the laser processing apparatus moves in the second direction.

17. The method of claim 12,
wherein the first lens group comprises first to third lenses sequentially arranged along a direction parallel to an optical axis of light traveling toward the carrier substrate, and
wherein a composite focal length of the first to third lenses is greater than about −1000 millimeters and less than about −300 millimeters.

18. The method of claim 17,
wherein each of the first lens and the third lens has a negative refractive power, and
wherein the second lens has a positive refractive power.

19. The method of claim 17, wherein each of the first lens, the second lens, and the third lens has a negative refractive power.

20. An electronic device comprising:
a display device manufactured by using the method of claim 12; and
a processor which transmits an image data signal and an input control signal to the display device.
